(19) United States
(12) Patent Application Publication
(10) Pub. No.: US 2023/0328898 A1
(43) Pub. Date: Oct. 12, 2023

(54) BOARD

(71) Applicant: TOYOTA JIDOSHA KABUSHIKI KAISHA, Toyota-shi (JP)

(72) Inventors: Miwako SHIONOYA, Okazaki-shi (JP); Satoko INUZUKA, Toyota-shi (JP); Rentaro MORI, Kasugai-shi (JP); Keiji KURODA, Toyota-shi (JP)

(73) Assignee: TOYOTA JIDOSHA KABUSHIKI KAISHA, Toyota-shi (JP)

(21) Appl. No.: 18/157,994

(22) Filed: Jan. 23, 2023

(30) Foreign Application Priority Data
Mar. 22, 2022 (JP) 2022-046023

(51) Int. Cl. H05K 3/38; H05K 3/00

(52) U.S. Cl. CPC H05K 3/387; H05K 3/0026

(57) ABSTRACT

Provided is a new board with a sufficient adhesion strength between an insulating layer and a metal layer. A board of the embodiment is a board including an insulating layer and a metal layer. The insulating layer contains a resin containing an insulating filler. The metal layer is disposed on a surface of the insulating layer. The resin is present partially between at least a part of the insulating filler present in the surface of the insulating layer and a metal constituting the metal layer. In an interface between the insulating layer and the metal layer, a depth of the metal present at a deepest portion in the insulating layer is 1.2 µm or less based on the resin or the insulating filler present in an outermost surface of the insulating layer.

### CROSS REFERENCE TO RELATED APPLICATIONS

The present application claims priority from Japanese Patent Application JP 2022-046023 filed on Mar. 22, 2022, the entire content of which is hereby incorporated by reference into this application.

### BACKGROUND

### Technical Field

The preset disclosure relates to a board.

### Background Art

Conventionally, a board used for a printed wiring board or the like is subjected to a treatment (roughening treatment) of roughening a surface of an insulating layer, for example, a desmear process, before forming a seed layer on the insulating layer from the aspect of improving an adhesion strength between the insulating layer and the seed layer.

As a method of roughening treatment, for example, a surface of an insulating layer is swollen using an ethylene glycol solution or the like, and subsequently, the insulating layer is roughened using a potassium permanganate solution or a sodium permanganate solution. The sequence of the operations is also referred to as a wet roughening.

In the wet roughening, since an insulating filler contained in the insulating layer is exposed from the surface of the insulating layer, and adhesion between the seed layer (for example, electroless copper-plated layer) and the insulating filler is low, an adhesion strength between the insulating layer and the seed layer has been consequently not sufficiently yet.

For example, JP 2017-199703 A discloses a wiring board that includes a wiring conductor formed by sequentially adhering an electroless copper-plated layer and an electrolytic copper-plated layer on a surface of an insulating layer formed of a thermosetting resin containing an inorganic insulating filler. The surface is subjected to a roughening treatment, and the inorganic insulating filler is not exposed from the surface. JP 2017-199703 A intends to improve an adhesion strength of the wiring conductor to the insulating layer surface by making the inorganic insulating filler not exposed.

### SUMMARY

The present disclosure provides a new board with a sufficient adhesion strength between an insulating layer and a metal layer thereof.

The inventors have seriously conducted studies to solve the above-described problem, and have found a board having a specific structure with a sufficient adhesion strength between an insulating layer and a metal layer, thus achieving the disclosure.

Examples of aspects of the embodiments are described as follows.
(1) A board comprises an insulating layer and a metal layer. The insulating layer contains a resin containing an insulating filler. The metal layer is disposed on a surface of the insulating layer. The resin is present partially between at least a part of the insulating filler present in the surface of the insulating layer and a metal constituting the metal layer. In an interface between the insulating layer and the metal layer, a depth of the metal present at a deepest portion in the insulating layer is 1.2 µm or less based on the resin or the insulating filler present in an outermost surface of the insulating layer.
(2) In the board according to (1), the metal layer includes one or more layers, and a layer in direct contact with the insulating layer of the metal layer is an electroless-plated layer or a dry-plated layer.
(3) In the board according to (1) or (2), the insulating layer is a layer obtained by performing a laser ablation on a surface of the resin containing the insulating filler.
(4) In the board according to (3), a laser light irradiated in the laser ablation is a laser light having a pulse width of 1 ps or less, a wavelength of 320 nm or more, and an output of 1 W or less.

The present disclosure can provide the new board with the sufficient adhesion strength between the insulating layer and the metal layer.

### BRIEF DESCRIPTION OF THE DRAWINGS

FIG. 1 is a schematic diagram in a case where a metal layer includes one or more layers and a layer in direct contact with an insulating layer of the metal layer is an electroless-plated layer in a board of an embodiment;

FIG. 2 is a schematic diagram in a case where a metal layer includes one or more layers and a layer in direct contact with the insulating layer of the metal layer is a dry-plated layer in the board of the embodiment;

FIG. 3 is a schematic diagram of a conventional board;

FIG. 4 is a conceptual diagram of an electrically conductive path in the metal layer close to the insulating layer of the board of the embodiment;

FIG. 5 is a conceptual diagram of an electrically conductive path in a metal layer close to an insulating layer of the conventional board;

FIG. 6 is a conceptual diagram for describing a depth of the metal in the board of the embodiment; and

FIG. 7 is a conceptual diagram for describing a depth of the metal in the board of the embodiment.

### DETAILED DESCRIPTION

The following describes a board of the embodiment in detail.

### Board

The board of the embodiment is a board that includes an insulating layer and a metal layer. The insulating layer contains a resin containing an insulating filler. The metal layer is disposed on a surface of the insulating layer. The resin is present partially between at least a part of the insulating filler present in the surface of the insulating layer and a metal constituting the metal layer. In an interface between the insulating layer and the metal layer, a depth of the metal present at the deepest portion in the insulating layer is 1.2 µm or less based on the resin or the insulating filler present in an outermost surface of the insulating layer.

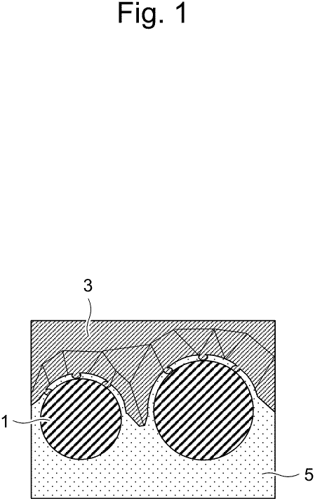

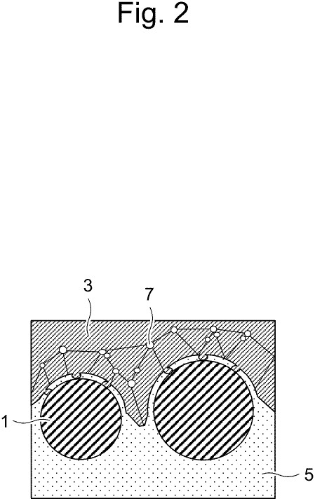

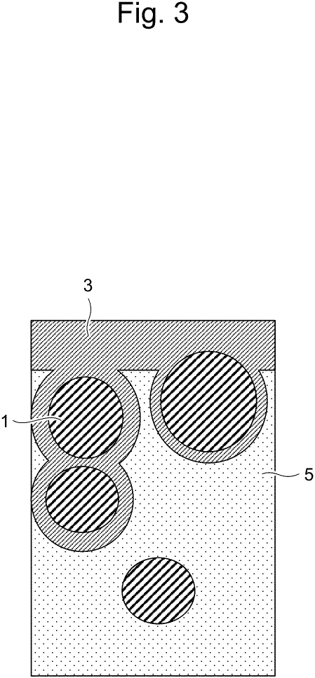

FIG. 1 and FIG. 2 illustrate schematic diagrams of the board of the embodiment. FIG. 1 is a schematic diagram in a case where a metal layer includes one or more layers and a layer in direct contact with an insulating layer of the metal layer is an electroless-plated layer. FIG. 2 is a schematic diagram in a case where a metal layer includes one or more layers and a layer in direct contact with the insulating layer of the metal layer is a dry-plated layer. FIG. 3 illustrates a schematic diagram of a board obtained by a conventional method, that is, a board in which a metal layer is formed on a surface of an insulating layer that has undergone a wet roughening by an electroless plating or the like. A board in which a metal layer is formed on a surface of an insulating layer that has undergone a wet roughening by an electroless plating or the like is also referred to as a conventional board. Examples of the metal constituting the metal layer include copper, gold, argentum, nickel, chrome, and tin, copper or gold may be used, or copper may be used in some embodiments.

In the board of the embodiment, the resin is present partially between at least a part of the insulating filler present in the surface of the insulating layer and the metal constituting the metal layer. In other words, the feature can be expressed as follows: that the resin is not present partially between at least a part of the insulating filler present in the surface of the insulating layer and the metal constituting the metal layer; or that in at least a part of the insulating filler present in the surface of the insulating layer and the metal constituting the metal layer, the filler is partially in direct contact with the metal. That is, as illustrated in FIG. 1 and FIG. 2, a resin 5 is present partially between at least a part of an insulating filler 1 and a metal 3, and at least a part of the insulating filler 1 is partially in direct contact with the metal 3.

Generally, it has been known that an adhesion strength is not satisfactory in the portion in which the insulating filler is in direct contact with the metal. However, it is considered that since the resin is present partially between the insulating filler and the metal in the board of the embodiment, a functional group of the resin improves the adhesion strength. It is also considered that the board of the embodiment has the portion in which the insulating filler is in direct contact with the metal, the board of the embodiment is excellent in heat dissipation performance as indicated by Reference Experiment 1 and Reference Experiment 2 described below.

Note that the present disclosure does not include an aspect in which the whole surface of the insulating filler is covered with the resin for all the fillers present in the surface of the insulating layer, in other words, an aspect in which the fillers are not in direct contact with the metal constituting the metal layer for all the fillers present in the surface of the insulating layer, and an aspect in which the whole surfaces of all the fillers present in the surface of the insulating layer are covered with the metal, in other words, an aspect in which the fillers are not in direct contact with the resin for all the fillers present in the surface of the insulating layer. As illustrated in FIG. 3, in a board in which a metal layer is formed on a surface of an insulating layer that has undergone a wet roughening by an electroless plating or the like, a resin 5 is not present on a surface of an insulating filler 1 present in the surface of the insulating layer, and the insulating filler 1 is covered with a metal 3.

In the board of the embodiment, in an interface between the insulating layer and the metal layer, a depth of the metal present at the deepest portion in the insulating layer is 1.2 µm or less based on the resin or the insulating filler present in an outermost surface of the insulating layer. The value of 1.2 µm or less is a value significantly reduced compared with the conventional board. As indicated by Comparative Example 1, in the conventional board, the depth of metal is, for example, about 2 µm.

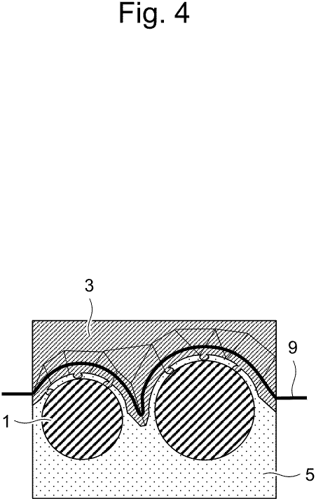

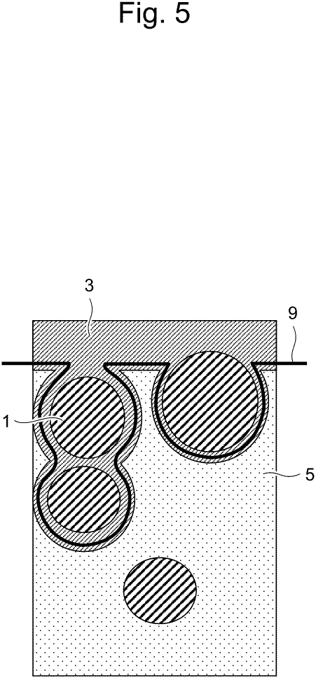

In the conventional board, the adhesion strength between the insulating layer and the metal layer is ensured by an anchor effect provided by the metal penetrating deep into the insulating layer. Meanwhile, in the board of the embodiment, since the depth of the metal penetrating into the insulating layer is smaller than that of the conventional one, it is considered that the anchor effect is reduced compared with the conventional board. However, since the resin is present partially between the filler and the metal, the sufficient adhesion strength can be ensured by the functional group of the resin. Additionally, since the metal layer does not penetrate deep into the insulating layer in the board of the embodiment, reduction in interlayer insulation distance can be suppressed compared with the conventional board in some embodiments, and an electrically conductive path of electricity flowing in the metal layer (for example, seed layer) close to the insulating layer can be shortened in the board of the embodiment compared with the conventional board in some embodiments. FIG. 4 illustrates a conceptual diagram of an electrically conductive path 9 in the metal layer close to the insulating layer of the board of the embodiment, and FIG. 5 illustrates a conceptual diagram of an electrically conductive path 9 in a metal layer close to an insulating layer of the conventional board.

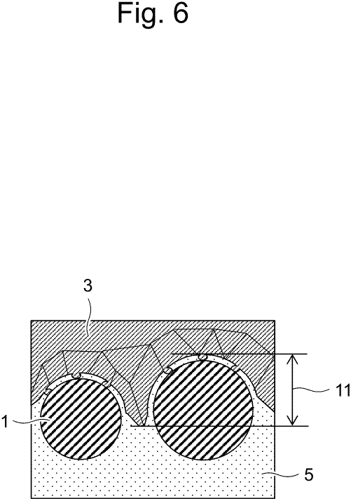

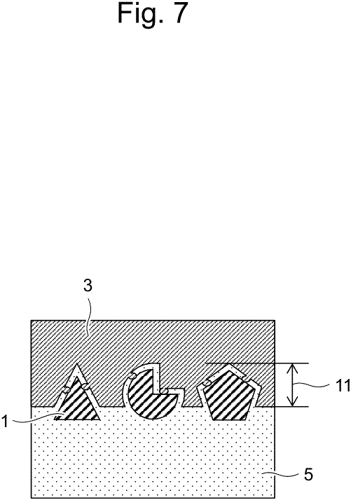

The above-described depth of the metal present at the deepest portion in the insulating layer in the interface between the insulating layer and the metal layer based on the resin or the insulating filler present in the outermost surface of the insulating layer means, for example, a depth 11 illustrated in FIG. 6. While the insulating filler 1 is illustrated in a spherical shape in FIG. 6, the shape of the insulating filler 1 is not limited thereto, and the depth 11 can be obtained similarly even when the shape of the insulating filler 1 is other than the spherical shape, for example, as illustrated in FIG. 7.

In the board of the embodiment, the metal layer may include one or more layers, and a layer in direct contact with an insulating layer of the metal layer may be an electroless-plated layer or a dry-plated layer in one aspect. When the metal layer includes one or more layers, the layer in direct contact with the insulating layer of the metal layer is also referred to as a seed layer. When the layer in direct contact with the insulating layer is an electroless-plated layer, the adhesion strength between the insulating layer and the metal layer tends to be especially excellent in some embodiments. When the layer in direct contact with the insulating layer is a dry-plated layer, a plating solution is not necessary in forming the layer, and this eliminates the need for liquid waste disposal in some embodiments. Note that when the layer in direct contact with the insulating layer is a dry-plated layer, as illustrated in FIG. 2, a hole or an oxide 7 is included in a part of the metal layer. When a hole or the oxide 7 is present in a part of the metal layer, for example, in an image obtained in a STEM observation, assuming that the whole seed layer having a thickness of, for example, 0.6 µm is a metal and an area of the seed layer is 100%, an area of the holes or the oxides 7 is more than 0% and 20% or less in some embodiments.

In the portion where the resin is present between the insulating filler present in the surface of the insulating layer and the metal constituting the metal layer, an average thickness of the resin may be from 3 nm to 20 nm, or may be from 5 nm to 18 nm in some embodiments.

While the resin is present partially between at least a part of the insulating filler present in the surface of the insulating layer and the metal constituting the metal layer, in the insulating filler and the metal constituting the metal layer, the filler is partially in direct contact with the metal as described above. In this case, a width of a portion without the resin (width of a portion in which the filler is in direct contact with the metal) may satisfy resin average thickness × 2 ≥ width of the portion without the resin relative to the average thickness of the resin in one aspect. When the relation is satisfied, the adhesion strength tends to be excellent in some embodiments.

The board of the embodiment may include another metal layer, or an electrolytic plated layer in some embodiments, on the above-described electroless-plated layer or dry-plated layer in one aspect. The board of the embodiment can be appropriately used as a wiring board.

In the board of the embodiment, the insulating layer may be a layer obtained by performing a laser ablation on a surface of the resin containing the insulating filler. The laser light irradiated in the laser ablation may be a laser light having a pulse width of 1 ps or less, a wavelength of 320 nm or more, and an output of 1 W or less. A method for manufacturing the board of the embodiment will be described in detail below.

### Method for Manufacturing Board

While the method for manufacturing the board of the embodiment is not especially limited, the board of the embodiment can be manufactured by forming an electroless-plated layer or a dry-plated layer on an insulating layer, and subsequently, forming an electrolytic plated layer on the electroless-plated layer or the dry-plated layer. The insulating layer may be a layer obtained by performing a laser ablation on a surface of a resin containing an insulating filler. The laser light irradiated in the laser ablation may be a laser light having a pulse width of 1 ps or less, a wavelength of 320 nm or more, and an output of 1 W or less.

For manufacturing the board of the embodiment, the laser ablation may be preliminarily performed to roughen a surface of the insulating layer. By performing the laser ablation under a specific condition, a large number of fine unevenness can be formed on a surface of the obtained board.

An object to be subjected to the laser ablation (insulating layer before laser ablation) is a layer containing a resin and an insulating filler, in other words, a layer that contains a resin containing an insulating filler. For example, a layer containing a resin and an insulating filler for forming a conventional wiring board can be used. Examples of the resin include polytetrafluoroethylene (PTFE), liquid crystal polymer (LCP), polyphenylene ether (PPE), modified polyphenylene ether (m-PPE), polyimide (PI), modified polyimide (MPI), bismaleimide triazine resin (BT), epoxy resin, and Low-k epoxy resin (low-dielectric constant (Low-Dk) and low-dielectric loss tangent (Low-Df) epoxy resin). The resin may be a high frequency-compatible low-dielectric board applicable to high-speed communications (for example, fifth-generation mobile communication systems and sixth-generation mobile communication systems) and millimeter-wave compatible communications (for example, automotive applications). When the laser ablation is performed on an object, the laser ablation is performed by irradiating a surface of the object with a specific laser light.

The object contains an insulating filler, and while the insulating filler is not especially limited, examples of the insulating filler include glass fiber, a silica-based filler, a ceramic-based filler, Al₂O₃, AlN, and BN. The size of the insulating filler is also not especially limited, and the size of the insulating filler can be appropriately set depending on the desired surface roughness of the insulating layer.

The object may have a single-layer structure including only a layer containing a resin and an insulating filler, and may have a structure (multi-layer structure) including two or more layers of the above-described layer and another layer. The other layer is not especially limited.

The laser light may be a laser light having a pulse width of 0.1 ps or more in one aspect. The pulse width may be 0.9 ps or less, or may be 0.85 ps or less in some embodiments. The pulse width may be 0.2 ps or more, or may be 0.3 ps or more in some embodiments.

The laser light may be a laser light having a wavelength of 1064 nm or less in one aspect. The wavelength of a laser light differs depending on a light source (laser medium), and for example, using Yb:YAG allows emitting a laser light having a wavelength of 1030 nm and a laser light having a wavelength of 515 nm (second harmonic), and using YAG allows emitting a laser light having a wavelength of 1064 nm, a laser light having a wavelength of 532 nm (second harmonic), a laser light having a wavelength of 355 nm (third harmonic), and a laser light having a wavelength of 266 nm (fourth harmonic). As the light source, for example, Yb:YAG, YAG, or the like can be used.

The laser light may have an output of 0.005 W to 0.200 W in one aspect. A scan rate in the laser light emission may be 500 mm/s to 1000 mm/s in one aspect.

An apparatus used in the laser ablation only needs to be capable of emitting the laser light, and is not especially limited. Examples of the apparatus include LodeStone (manufactured by Esi) and Monaco series (COHERENT, Inc.).

The insulating layer (object after laser ablation) may have an arithmetic mean height Sa of 50 nm to 250 nm in one aspect. The arithmetic mean height Sa can be measured using a laser roughness meter. In the method for manufacturing the board of the embodiment, an electroless-plated layer or a dry-plated layer may be formed on the insulating layer (object after laser ablation) subsequently to the laser ablation.

As the method for forming the electroless-plated layer on the insulating layer, it is only necessary to perform an electroless plating on the surface of the insulating layer, and its condition is not especially limited. An electroless plating solution can be selected depending on a metal type contained in the plated layer, electroless plating solutions including a publicly known autocatalytic electroless plating solution can be used without being especially limited. As the electroless plating solution, an electroless copper plating solution, an electroless gold plating solution, an electroless silver plating solution, an electroless nickel plating solution, an electroless chrome plating solution, and the like can be used, and an electroless copper plating solution is usually used in the usage for wiring boards. As the plating condition of the electroless plating, publicly known conditions are applicable as necessary. The electroless-plated layer may have an average thickness of 0.6 µm or less, may have an average thickness of 0.16 µm to 0.24 µm, or may have an average thickness of 0.18 µm to 0.22 µm in some embodiments. The electroless-plated layer may be an electroless copper-plated layer in one aspect. In the board in which the electroless-plated layer is formed on the insulating layer, especially, the metal layer and the board are strongly coupled and a peel strength is high in some embodiments. The board of the embodiment does not include an adhesive layer formed from Cr or Ti that was provided in performing the conventional dry plating, and is excellent in adhesion strength between the plated layer and the board in some embodiments.

As the method for forming the dry-plated layer on the insulating layer (object after laser ablation), it is only necessary to perform a dry plating on the surface of the insulating layer, and its condition is not especially limited. Examples of the dry plating include a sputtering method, an ion plating method, and a vacuum evaporation method. As the dry plating, a sputtering method may be employed from the aspect of the adhesion strength with the insulating layer. That is, the dry-plated layer may be a sputtered layer in one aspect. When the dry plating is performed, copper, gold, argentum, nickel, chrome, tin, or the like can be used as a target, and copper is usually used in the usage for wiring boards.

The dry plating can be performed by applying publicly known conditions as necessary. That is, the dry plating can be performed by a publicly known sputtering method, ion plating method, vacuum evaporation method, or the like. The dry-plated layer may have an average thickness of 1 µm or less, may have an average thickness of 0.15 µm to 0.9 µm, or may have an average thickness of 0.16 µm to 0.8 µm in some embodiments. The dry-plated layer may be a dry copper-plated layer in one aspect. The board in which the dry-plated layer is formed on the insulating layer has a sufficient peel strength even though the metal layer adjacent to the insulating layer is a dry-plated layer formed by dry plating generally having a difficulty in coupling to the insulating layer. The dry plating tends to apply less load on the environment, for example, not generating waste liquid, compared with an electroless plating as a type of wet plating, and the dry plating may be employed from the aspect of reducing the environmental load.

A plasma treatment may be performed on the surface of the insulating layer before forming the dry-plated layer on the insulating layer in one aspect. Since an amount of the functional group of the resin in the insulating layer can be further increased, the plasma treatment may be performed. While it is the most effective to perform the plasma treatment before forming the dry-plated layer, the plasma treatment may be performed before forming the electroless-plated layer.

The plasma treatment may be at least one kind of plasma treatment selected from an H₂/Ar plasma treatment and an O₂/Ar plasma treatment. The H₂/Ar plasma treatment is a method of performing a plasma treatment on a board using hydrogen and argon, and the O₂/Ar plasma treatment is a method of performing a plasma treatment on a board using oxygen and argon, and the H₂/Ar plasma treatment and the O₂/Ar plasma treatment can be each performed by appropriately applying publicly known conditions. As the plasma treatment, the H₂/Ar plasma treatment and the O₂/Ar plasma treatment may be performed, and the O₂/Ar plasma treatment may be performed after performing the H₂/Ar plasma treatment in some embodiments. Performing the H₂/Ar plasma treatment can provide a clean surface, and subsequently performing the O₂/Ar plasma treatment can introduce the functional group.

In the method for manufacturing the board of the embodiment, an electrolytic plated layer may be formed by performing an electrolytic plating on an electroless-plated layer or a dry-plated layer after forming the electroless-plated layer or the dry-plated layer.

As an electrolytic plating solution, an electrolytic copper plating solution, an electrolytic gold plating solution, an electrolytic silver plating solution, an electrolytic nickel plating solution, an electrolytic chrome plating solution, an electrolytic tin plating solution, or the like can be used. For the application of wiring boards, the electrolytic copper plating solution is usually used. As the plating conditions of the electrolytic plating, publicly known conditions can be appropriately applied. In some embodiments, as the electrolytic plating, a solid electrolyte deposition (SED) that is a plating method using a solid-state electrolyte membrane may be employed. For the application of wiring boards, the electrolytic plated layer may have an average line width of wiring (simply referred to also as width) of 30 µm or less, may have an average line width of 10 µm or less, or may have an average line width of 5 µm or less in some embodiments. In addition, the average line width may be 1 µm or more. From the aspect of micro wiring, the aspect ratio (thickness/width) of the thickness to the width of the wiring may be 0.85 to 1.15, or may be 0.9 to 1.1 in some embodiments. The electrolytic plated layer may be an electrolytic copper plated layer in one aspect. The electroless plated layer and the electrolytic plated layer, or the dry plated layer and the electrolytic plated layer may be layers formed from the same type of metal, or may be layers formed from copper in some embodiments.

In the method for manufacturing the board of the embodiment, a heat treatment may be performed after the electrolytic plating. The heat treatment is also referred to as firing or an annealing treatment.

The heat treatment is generally performed by heating a board in which an electrolytic plated layer is formed. While the heating temperature differs depending on the type of the resin contained in the board, the metal type contained in the plated layer, and the like, the heating temperature may be, for example, 100° C. to 210° C., or may be 110° C. to 200° C. in some embodiments. The heat treatment is usually performed by heating the board at a temperature, which is a glass transition point (Tg) or more of the resin contained in the insulating layer, and for a time period in which its shape retention is secured. In the heat treatment, the temperature may be gradually raised from a low temperature in one aspect. For example, when the Tg of the resin contained in the board is 150° C., the heat treatment can be performed at 100° C. to 140° C., or may be performed at 110° C. to 140° C. in some embodiments, and subsequently, the heat treatment can be performed at 150° C. to 210° C., or may be performed at 150° C. to 200° C. in some embodiments. When the heat treatment is performed at a constant temperature, the heat treatment is performed, for example, at 150° C. to 210° C., or may be performed at 160° C. to 200° C. in some embodiments. In the heat treatment, heating at the temperature of the Tg of the resin or more is performed usually for 10 minutes to 90 minutes, or may be performed for 30 minutes to 60 minutes in some embodiments. When the heat treatment is performed while gradually raising the temperature from a low temperature, the phases are each performed usually for 10 minutes to 90 minutes, or may be performed for 30 minutes to 60 minutes in some embodiments.

The heat treatment may be performed in the air, and may be performed in an inert gas such as nitrogen or a noble gas. From the aspect of cost, the heat treatment is performed in the air in some embodiments, and from the aspect of suppressing a side reaction, the heat treatment is performed in an inert gas in some embodiments.

While the heat treatment may be performed under a normal pressure, under a reduced pressure, or under an increased pressure, the heat treatment is usually performed under a normal pressure.

The method for manufacturing the board of the embodiment may further include conventionally-publicly known another process. For example, when the board is a wiring board, the electrolytic plated layer can be formed, for example, after applying a resist over the metal layer of the board and performing a patterning, and an etching can be performed after the electrolytic plating. The above-described firing can be performed after the etching.

### EXAMPLES

While the following describes the embodiments using Examples, the present disclosure is not limited thereto.

In the examples, a board below was used.

ABF films (ABF GX92, manufactured by Ajinomoto Fine-Techno Co., Inc.) were attached to both surfaces of a glass epoxy board (epoxy resin containing a glass fiber) (FR-4), in which a copper foil was disposed on both surfaces thereof, by heat pressing, thus producing the board.

The board was cut in a size of 50 mm × 50 mm, and used as the board for evaluation in each of examples and comparative examples.

While ABF GX92 is distributed in a state where a layer formed of an insulating material (epoxy resin containing a silica-based filler) is disposed on a PET film, in the example, the PET film was peeled off, and the layer formed from the insulating material (epoxy resin containing a silica-based filler) was attached to the glass epoxy board. In each of the examples and the comparative examples, a surface of the layer formed of the insulating material was used as an object subjected to the laser ablation or the wet roughening. The surface of the layer formed of the insulating material is also referred to as a surface of an ABF film.

### Example 1

### Roughening Step

Laser ablation (target roughness Sa 200 nm) was performed by irradiating the surface of the ABF film with a laser light under the conditions below.

### Laser Irradiation Conditions

Device: LodeStone (manufactured by Esi)
Wavelength: 515 nm
Pulse Width: 0.8 ps
Beam Diameter: ϕ 10 µm
Output: 0.15 W
Repetition Frequency: 100 KHz
Scanning Rate: 500 mm/s
Overlap: 5 µm

### Seed Layer Forming Step (Electroless Copper Plating Step)

The surface of the ABF film that had undergone the laser ablation was pickled using sulfuric acid, and subsequently, an electroless copper plating was performed under the conditions below, thus forming an electroless copper-plated layer.

### Electroless Copper Plating

Electroless Copper Plating Solution: PEA ver.3 (manufactured by C. Uyemura & Co., Ltd.)
Process Temperature: 33° C.
Immersion Period: 30 minutes
Electroless Copper-Plated Layer Average Thickness: 0.2 µm

### Electrolytic Copper-Plated Layer Forming Step

An electrolytic copper plating was performed on the electroless copper-plated layer under the conditions below, thus forming an electrolytic copper-plated layer.

### Electrolytic Copper Plating

Electrolytic Copper Plating Solution: prepared based on Cover Cream 125A · 125B (manufactured by Rohm and Haas Company)
Film Forming Rate: 0.67 µm/minute
Plating Period: 30 minutes
Electrolytic Copper-Plated Layer Average Thickness: 20 µm

### Heat Treatment Step

The board in which the electrolytic copper-plated layer was formed was put into a firing furnace, and a heat treatment was performed in an air atmosphere at 120° C. for 30 minutes. Subsequently, the temperature was raised, and the heat treatment was performed at 200° C. for 60 minutes, and after that, the board was naturally cooled to 50° C. in the firing furnace. Subsequently, the board was taken out from the firing furnace and left until the temperature became room temperature, thus obtaining a board including an electrolytic copper-plated layer.

### Peel Strength Measurement

The peel strength of the board including the electrolytic copper-plated layer was measured by the method below.

A slit having a width of 5 mm was made in the electrolytic copper-plated layer using a cutter knife, and the peel strength (kN/m) was measured with a tensile compression testing machine (EZ TEST SHIMAZU). A peeling direction was a direction of 90° with respect to the board, a peeling rate was 50 mm/min, and a peeling length was 30 mm.

The peel strength was 0.80 kN/m.

### Cross-Sectional STEM Observation and Analysis

For the board including the electrolytic copper-plated layer, a periphery of an interface between the ABF film and the seed layer was observed with a Scanning Transmission Electron Microscopy (STEM), and STEM-EELS analysis (EELS: Electron Energy-Loss Spectroscopy) was performed.

For the board including the electrolytic copper-plated layer, a thin film of 10×10 µm² and t = 80 nm was produced from the periphery of the interface between the ABF film and the seed layer by FIB-micro sampling.
Apparatus: FIB-SEM (manufactured by Hitachi High-Technologies Corporation (current name: Hitachi High-Tech Corporation): NB-5000)
The thin film was produced in a sample chamber according to the usual method of FIB-micro sampling method including surface protection, peripheral processing, bottom cutting, probe bonding, support cutting, extraction, fixing, probe cutting, and thin film processing in this order.

EELS-line measurement was performed in the interface between copper (seed layer) and filler (ABF film), and presence/absence of carbon peak was confirmed.
Apparatus: Cs-STEM (manufactured by JEOL: JEM-ARMF300), EELS (Gatan: Quantum)
Analysis Condition: accelerating voltage 200 kV, EELS line analysis, analyzed in increments of 0.2 nm of step

Measurement Portion: Line analysis was performed at three positions for one filler in the interface between the filler present in the surface of the ABF film and copper, in the interface between the seed layer and the ABF film. The line analysis was performed for two fillers. That is, the line analysis was performed at six positions in total for two fillers per thin film.

As a result of the EELS line analysis, it was determined that the resin was present between the filler and the copper when the carbon peak was detected, and it was determined that the filler was in direct contact with the copper when the carbon peak was not detected.

When the carbon peak was detected, the thickness of the resin was measured from the peak width of the carbon peak.

As a result of the analysis, the carbon was detected at four positions, and the carbon was not detected at two positions in the six positions of the line analysis. The average resin thickness at the four positions at which the carbon was detected was 10 nm.

### Measurement of Copper Penetration Depth

For the board including the electrolytic copper-plated layer, STEM observation was performed, and HAADF image was obtained.

In the obtained HAADF image, a depth of the copper present at the deepest portion in the ABF film was measured based on the resin or the filler present in the outermost surface of the ABF film.

The depth of the copper was 1.1 µm.

### Example 2

### Roughening Step

The surface of the ABF film was irradiated with a laser light under the conditions similarly to those in Example 1, and the laser ablation (targeted roughness Sa of 200 nm) was performed.

### Seed Layer Forming Step (Copper Sputtering Step)

An H₂/Ar plasma treatment and an O₂/Ar plasma treatment were sequentially performed on the surface of the ABF film that had undergone the laser ablation, under the conditions below, and subsequently, a copper sputtering was performed under the conditions below, thus forming a sputtered copper layer.

### H₂/Ar Plasma Treatment Conditions

Hydrogen 3%/Argon 97% (volume fraction)
Apparatus: High-speed sputtering apparatus (manufactured by Shimadzu Corporation)
Pressure: 30 Pa
Output: 1750 W
Processing Period: 60 seconds
TS (distance between anode plasma source and board sample (stage)): 180 mm
BGP (background pressure): 0.5 Pa
(O₂/Ar Plasma Treatment Conditions)
O₂/Ar = 1520 sccm/80 sccm
Apparatus: High-speed sputtering apparatus (manufactured by Shimadzu Corporation)
Pressure: 30 Pa
Output: 2100 W
Processing Period: 180 seconds
TS: 180 mm
BGP: 0.5 Pa

### Copper Sputtering

Sputtering Source: copper
Power Source: 35 KW
Argon Flow Rate: 270 sccm
Gas Pressure: 1.6 Pa
Sputtering Period: 10 seconds
TS: 180 mm
BGP: 0.5 Pa
Sputtered Copper Layer Average Thickness: 0.6 µm

### Electrolytic Copper-Plated Layer Forming Step

An electrolytic copper plating was performed on the sputtered copper layer under the conditions similarly to those in Example 1, thus forming an electrolytic copper-plated layer.

### Heat Treatment Step

A heat treatment was performed on the board in which the electrolytic copper-plated layer was formed under the conditions similarly to those in Example 1, thus obtaining a board including an electrolytic copper-plated layer.

### Peel Strength Measurement

The peel strength of the board including the electrolytic copper-plated layer was measured by the method similarly to that of Example 1.

The peel strength was 0.60 kN/m.

### Cross-Sectional STEM Observation and Analysis

For the board including the electrolytic copper-plated layer, STEM observation and STEM-EELS analysis were performed on a periphery of an interface between the ABF film and the seed layer by the method similarly to that of Example 1.

As a result of the analysis, the carbon was detected at five positions, and the carbon was not detected at one position in the six positions of the line analysis. The average resin thickness at the five positions at which the carbon was detected was 5 nm.

### Measurement of Copper Penetration Depth

For the board including the electrolytic copper-plated layer, STEM observation was performed, and HAADF image was obtained.

In the obtained HAADF image, a depth of the copper present at the deepest portion in the ABF film was measured based on the resin or the filler present in the outermost surface of the ABF film.

The depth of the copper was 0.73 µm.

### Comparative Example 1

### Roughening Step

A wet roughening (targeted roughness Sa of 200 nm) was performed on the surface of the ABF film by a desmear process using permanganic acid.

### Seed Layer Forming Step (Electroless Copper Plating Step)

The surface of the ABF film that had undergone the wet roughening was pickled using sulfuric acid, and subsequently, an electroless copper plating was performed under the conditions similarly to those in Example 1, thus forming an electroless copper-plated layer.

### Electrolytic Copper-Plated Layer Forming Step

An electrolytic copper plating was performed on the electroless copper-plated layer under the conditions similarly to those in Example 1, thus forming an electrolytic copper-plated layer.

### Heat Treatment Step

The board in which the electrolytic copper-plated layer was formed was put into a firing furnace, and a heat treatment was performed in an air atmosphere at 180° C. for 30 minutes. Subsequently, the board was naturally cooled to 50° C. in the firing furnace, and after that, the board was taken out from the firing furnace and left until the temperature became room temperature, thus obtaining a board including an electrolytic copper-plated layer.

### Peel Strength Measurement

The peel strength of the board including the electrolytic copper-plated layer was measured by the method similarly to that of Example 1.

The peel strength was 0.61 kN/m.

### Cross-Sectional STEM Observation and Analysis

For the board including the electrolytic copper-plated layer, STEM observation and STEM-EELS analysis were performed on a periphery of an interface between the ABF film and the seed layer by the method similarly to that of Example 1.

As a result of the analysis, the carbon was not detected at six positions in the six positions of the line analysis.

### Measurement of Copper Penetration Depth

For the board including the electrolytic copper-plated layer, STEM observation was performed, and HAADF image was obtained.

In the obtained HAADF image, a depth of the copper present at the deepest portion in the ABF film was measured based on the resin or the filler present in the outermost surface of the ABF film.

The depth of the copper was 1.9 µm.

### Reference Experiment 1

For analyzing how much the thickness of the resin affects the heat dissipation performance when the resin is present between the filler in the insulating layer and the metal layer, a heat transfer simulation described below was performed.
Calculation Method: Thermal Network Method (heat transfer simulation)
Preconditions
Analytical Model: a stacked structure of copper (thickness 10 µm)/resin (thickness X)/filler (thickness 1 µm)/resin (thickness 20 µm) was used as a model.

X was 0.01 µm, 0.05 µm, 0.1 µm, 0.2 µm, 0.4 µm, 0.6 µm, 0.8 µm, or 1.0 µm.

In the stacked structure, a surface of the copper was a heat generating surface, and a surface (which is a surface the farthest from the copper) of the resin having the thickness of 20 µm was a back surface.

The analysis was performed assuming that a heat amount with which the temperature of the heat generating surface became 104.9° C. was given when X was 1.0 µm. An initial temperature of the back surface was set to 20° C.

It was evaluated that the lower the temperature of the copper surface (heat generating surface) in a steady state was, the higher the heat dissipation performance was.

Table 1 illustrates a relation between X and the copper surface temperature (heat generating surface temperature).

TABLE 1

| X (µm) | Copper Surface Temperature (°C) |
|---|---|
| 1.0 | 104.9 |
| 0.8 | 104.1 |
| 0.6 | 103.3 |
| 0.4 | 102.5 |
| 0.2 | 101.7 |
| 0.1 | 101.3 |
| 0.05 | 101.1 |
| 0.01 | 101.0 |

Table 1 indicates that the thin thickness of the resin between the filler and the copper lowered the copper surface temperature. That is, it was suggested that the thin thickness of the resin between the filler and the copper provided the high heat dissipation performance.

### Reference Experiment 2

For analyzing whether or not the heat dissipation performance changes in a case where the resin is present between the filler in the insulating layer and the metal layer by 90% (area%), the resin is not present in the part of 10%, and the metal is in direct contact with the filler in the part of 10% compared with a case where the metal is not in direct contact with the filler, a heat transfer simulation described below was performed.
Calculation Method: thermal network method (heat transfer simulation)
Preconditions
Analytical Model: a stacked structure of copper (thickness 10 µm)/resin (thickness 0.01 µm)/filler (thickness 1 µm)/resin (thickness 20 µm) was used as a model.

However, in the resin having the thickness of 0.01 µm, a part of 10% was copper not the resin. (That is, a model in which a part (10%) of the filler was in direct contact with the copper was employed.)

The experiment was performed similarly to Reference Experiment 1 except that the model having the above-described stacked structure was employed, and the copper surface temperature (heat generating surface temperature) was calculated. The copper surface temperature (heat generating surface temperature) was 99.3° C.

From Reference Experiment 1 and Reference Experiment 2, it was indicated that the heat dissipation performance was more excellent in the case where the filler was in direct contact with the copper than the case where the resin was entirely present between the filler and the copper.

Upper limit values and/or lower limit values of respective numerical ranges described in this description can be appropriately combined to specify an intended range. For example, upper limit values and lower limit values of the numerical ranges can be appropriately combined to specify an intended range, upper limit values of the numerical ranges can be appropriately combined to specify an intended range, and lower limit values of the numerical ranges can be appropriately combined to specify an intended range.

While the embodiments have been described in detail, the specific configuration is not limited to the embodiments. Design changes within a scope not departing from the gist of the present disclosure are included in the present disclosure.

DESCRIPTION OF SYMBOLS

| | |
|---|---|
| 1 | Insulating filler |
| 3 | Metal |
| 5 | Resin |
| 7 | Hole or oxide |
| 9 | Electrically conductive path |
| 11 | Depth |

What is claimed is:

1. A board comprising:
an insulating layer that contains a resin containing an insulating filler; and
a metal layer disposed on a surface of the insulating layer,
wherein the resin is present partially between at least a part of the insulating filler present in the surface of the insulating layer and a metal constituting the metal layer, and
wherein in an interface between the insulating layer and the metal layer, a depth of the metal present at a deepest portion in the insulating layer is 1.2 µm or less based on the resin or the insulating filler present in an outermost surface of the insulating layer.

2. The board according to claim 1,
wherein the metal layer includes one or more layers, and a layer in direct contact with the insulating layer of the metal layer is an electroless-plated layer or a dry-plated layer.

3. The board according to claim 1,
wherein the insulating layer is a layer obtained by performing a laser ablation on a surface of the resin containing the insulating filler.

4. The board according to claim 3,
wherein a laser light irradiated in the laser ablation is a laser light having a pulse width of 1 ps or less, a wavelength of 320 nm or more, and an output of 1 W or less.
